(19) United States
(12) Patent Application Publication
(10) Pub. No.: US 2018/0308972 A1
(43) Pub. Date: Oct. 25, 2018

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Naoyuki OHSE, Matsumoto-city (JP); Yusuke KOBAYASHI, Tsukuba-city (JP); Takahito KOJIMA, Matsumoto-city (JP)

(73) Assignee: FUJI ELECTRIC CO., LTD., Kawasaki-shi (JP)

(21) Appl. No.: 15/941,835

(22) Filed: Mar. 30, 2018

(30) Foreign Application Priority Data
Apr. 20, 2017 (JP) 2017-084062

(51) Int. Cl. H01L 29/78; H01L 29/16; H01L 29/10; H01L 29/47; H01L 29/66; H01L 21/04

(52) U.S. Cl. CPC H01L 29/7806; H01L 29/1608; H01L 29/1095; H01L 29/47; H01L 21/0495; H01L 29/7813; H01L 29/66068; H01L 21/046; H01L 29/7811

(57) ABSTRACT

At a front surface of a semiconductor base, an n⁻-type drift layer, a p-type base layer, an n⁺⁺-type source region, an n⁺⁺-type source region, a p-type base layer, and a trench that reaches the n⁻-type drift layer are provided. The silicon carbide semiconductor device has a recess provided between adjacent trenches. The recess has a side surface and a bottom surface that form an angle of 15° to 80°. A SBD part is provided at the bottom surface of the recess and forms a Schottky contact with the n⁻-type drift layer.

### CROSS REFERENCE TO RELATED APPLICATIONS

This application is based upon and claims the benefit of priority of the prior Japanese Patent Application No. 2017-084062, filed on Apr. 20, 2017, the entire contents of which are incorporated herein by reference.

### BACKGROUND OF THE INVENTION

### 1. Field of the Invention

Embodiments of the invention relate to a silicon carbide semiconductor device and a method of manufacturing a silicon carbide semiconductor device.

### 2. Description of the Related Art

Insulated gate type metal oxide semiconductor field effect transistors (MOSFETs) sustaining voltages of 400V, 600V, 1200V, 1700V, 3300V, 6500V or higher are commonly known power semiconductor devices. For example, insulated gate type MOSFETs that use silicon carbide (SiC) (hereinafter, SiC-MOSFETs) are employed in power converting equipment such as converters and inverters. There is demand for these power semiconductor devices to have low loss and high efficiency while at the same time reduce leak current in an OFF state, facilitate size reductions, and improve reliability.

A vertical MOSFET has, as a body diode between the source and drain, an internal parasitic pn diode formed by a p-type base region and an n-type drift layer. Therefore, a freewheeling diode (FWD) used in an inverter may be omitted, contributing to reductions in cost and size. Nonetheless, when a silicon carbide substrate is used as a semiconductor substrate, compared to a case where a silicon (Si) substrate is used, the parasitic pn diode has a high built-in potential whereby the ON resistance of the parasitic pn diode increases, leading to increased loss. Further, when the parasitic pn diode is turned on and current passes through, characteristics change over time (aging) and reliability decreases due to bipolar operation of the parasitic pn diode.

To address this problem, in a circuit, a Schottky barrier diode (SBD) is connected in parallel to a MOSFET, whereby at the time of flyback, current flows in the SBD, enabling a state where current does not flow through the parasitic pn diode. Nonetheless, cost increases because the number of SBD chips required is approximately equal to that of the MOSFETs.

Therefore, since connection of the SBD to an n-type drift layer and a source electrode is necessary, a technique has been proposed where a contact trench that penetrates a p-type channel part is formed at a substrate surface and the SBD is incorporated at a trench inner wall, whereby current at the time of flyback flows through the built-in SBD and not a PiN diode (for example, refer to Japanese Laid-Open Patent Publication No. H8-204179).

FIG. 12 is a cross-sectional view of a structure of a conventional silicon carbide semiconductor device with a built-in SBD. As depicted in FIG. 12, a conventional example includes on a front surface of an n⁺-type silicon carbide substrate 31, a trench-type MOS gate (insulated gate using a metal-oxide-film semiconductor material) structure and a contact trench 324. More specifically, an n⁻-type layer constituting an n⁻-type drift layer 32 is formed by epitaxial growth on an n⁺-type silicon carbide substrate 31. On the front surface (surface facing the n⁻-type drift layer 32) side of the n⁺-type silicon carbide substrate 31, a MOS gate structure is provided constituted by a p-type base layer 36, an n⁺⁺-type source region 37, a trench 318, a gate insulating film 39, and a gate electrode 310.

Further, on a rear surface of the n⁺-type silicon carbide substrate 31, a drain electrode 316 is provided. The contact trench 324 is a trench that is covered by a Schottky metal connecting the inner wall to a source electrode 312. The contact trench 324 forms a Schottky junction of a semiconductor region exposed at the inner wall and the Schottky metal. In this manner, in FIG. 12, between the source and drain, a parasitic Schottky diode is provided in parallel with a parasitic pn diode.

When positive voltage is applied to the source electrode 312 and negative voltage is applied to the drain electrode 316 (when the MOSFET is OFF), a pn junction between the p-type base layer 36 and the n⁻-type drift layer 32 is forward biased. In FIG. 12, design is such that when the MOSFET is OFF, the parasitic Schottky diode turns ON before the parasitic pn diode turns ON, whereby bipolar operation of the parasitic pn diode is suppressed, enabling aging due to the bipolar operation to be prevented.

Another technology includes a Schottky region between trenches. For example, a Schottky device and a MOSFET are both formed and included on a common die, where trench-type MOSFETs each includes plural trenches supporting a gate structure and the Schottky device is arranged at a most superficial surface of the die and includes a Schottky barrier forming a Schottky contact at a part of the surface as well as Schottky regions respectively arranged between trench groups of the MOSFET device (for example, refer to Japanese Laid-Open Patent Publication No. 2005-57291).

### SUMMARY OF THE INVENTION

According to an embodiment of the present invention, a silicon carbide semiconductor device includes a semiconductor substrate of a first conductivity type; a first semiconductor layer of the first conductivity type provided on a front surface of the semiconductor substrate; a second semiconductor layer of a second conductivity type provided on a first side of the first semiconductor layer opposite a second side of the first semiconductor layer, the second side facing the semiconductor substrate; a first semiconductor region of the first conductivity type selectively provided in the second semiconductor layer, an impurity concentration of the first semiconductor region being higher than an impurity concentration of the semiconductor substrate; a trench penetrating the first semiconductor region and the second semiconductor layer, and reaching the first semiconductor layer; a gate electrode provided in the trench, via gate insulating film; a first electrode in contact with the first semiconductor region and the second semiconductor layer; a second electrode provided on a rear surface of the semiconductor substrate; a recess provided between the trench and an adjacent trench, the recess having a side surface and a bottom surface forming an angle of 15° to 80°; and a metal electrode provided at the bottom surface of the recess and forming a Schottky contact with the first semiconductor layer.

In the embodiment, the silicon carbide semiconductor device further includes a second semiconductor region of the second conductivity type selectively provided in the first semiconductor layer, the second semiconductor region being in contact with a bottom of the trench, an impurity concentration of the second semiconductor region being higher than an impurity concentration of the second semiconductor layer; and a third semiconductor region of the second conductivity type selectively provided in the first semiconductor layer, an impurity concentration of the third semiconductor region being higher than the impurity concentration of the second semiconductor layer. A width of the metal electrode is equivalent to a distance between the second semiconductor region and the third semiconductor region.

In the embodiment, the silicon carbide semiconductor device further includes an active region provided at the semiconductor substrate, and through which a main current flows; and a termination region surrounding a periphery of the active region. The metal electrode is provided in the active region and parallel to the trench. An end of the trench is provided at least 0.5 μm beyond an end of the metal electrode, toward the termination region. An interval between metal electrode and an adjacent metal electrode is less than 240 μm.

In the embodiment, the interval between the metal electrode and the adjacent metal electrode is less than 160 μm.

In the embodiment, the metal electrode and first electrode have a common upper electrode.

In the embodiment, the metal electrode is constituted by a metal film covering the active region entirely.

In the embodiment, the metal electrode is constituted by a metal film covering only a region of the active region in which a MOS gate structure is provided.

In the embodiment, the silicon carbide semiconductor device further includes an active region provided at the semiconductor substrate, and through which a main current flows; and a termination region surrounding a periphery of the active region. The metal electrode is provided in the termination region so as to surround the active region.

In the embodiment, the metal electrode is provided only at the bottom surface and a part of the side surface of the recess.

In the embodiment, the metal electrode contains one among Ti, Ni, W, Mo, Au, and Pt.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a structure of the silicon carbide semiconductor device according to a first embodiment;

FIG. 2 is a top view of the structure of the silicon carbide semiconductor device according to the first embodiment;

FIG. 3 is an enlarged view of a region S depicted in FIG. 2 of the silicon carbide semiconductor device according to the first embodiment;

FIG. 4 is a graph depicting a relationship of SBD width and current ratio of the parasitic pn diode and the SBD in the silicon carbide semiconductor device according to the first embodiment;

FIG. 5 is a cross-sectional view of the silicon carbide semiconductor device according to the first embodiment during manufacture;

FIG. 6 is a cross-sectional view of the silicon carbide semiconductor device according to the first embodiment during manufacture;

FIG. 7 is a cross-sectional view of the silicon carbide semiconductor device according to the first embodiment during manufacture;

FIG. 8 is a cross-sectional view of a structure of the silicon carbide semiconductor device according to the second embodiment;

FIG. 9 is a top view of the structure of the silicon carbide semiconductor device according to the second embodiment;

FIG. 10 is a cross-sectional view of a structure of the silicon carbide semiconductor device according to the third embodiment;

FIG. 11 is a cross-sectional view of a structure of the silicon carbide semiconductor device according to the fourth embodiment; and

FIG. 12 is a cross-sectional view of a structure of a conventional silicon carbide semiconductor device with a built-in SBD.

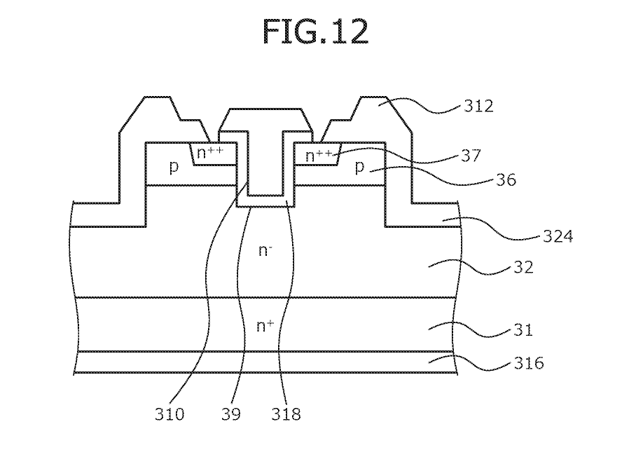

### DETAILED DESCRIPTION OF THE INVENTION

First, problems associated with the related arts will be described. In Japanese Laid-Open Patent Publication No. H8-204179, formation of a SBD at the trench inner wall is necessary, and uniform deposition of the Schottky metal at the trench inner wall is necessary. The complexity of this process is high and when process problems such as incomplete coverage of the trench inner wall occur, yield rate does not increase. Further, the number of processes increases since the two trenches (the gate trench and the contact trench) have to be formed by separate processes. Moreover, patterning of a Schottky electrode is necessary, and when the cell pitch is reduced with reductions in size, the complexity of this process also becomes high, making fabrication of the Schottky electrode difficult.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical will be given the same reference numerals and will not be repeatedly described. Further, in the present description, when Miller indices are described, “−” means a bar added to an index immediately after the “−”, and a negative index is expressed by prefixing “−” to the index.

A semiconductor device according to an embodiment of the present invention is configured using a semiconductor material (hereinafter, wide bandgap semiconductor material) having a bandgap wider than that of silicon. Here, a silicon carbide semiconductor device fabricated using, for example, silicon carbide (SiC) as a wide bandgap semiconductor material will be described taking a MOSFET as an example.

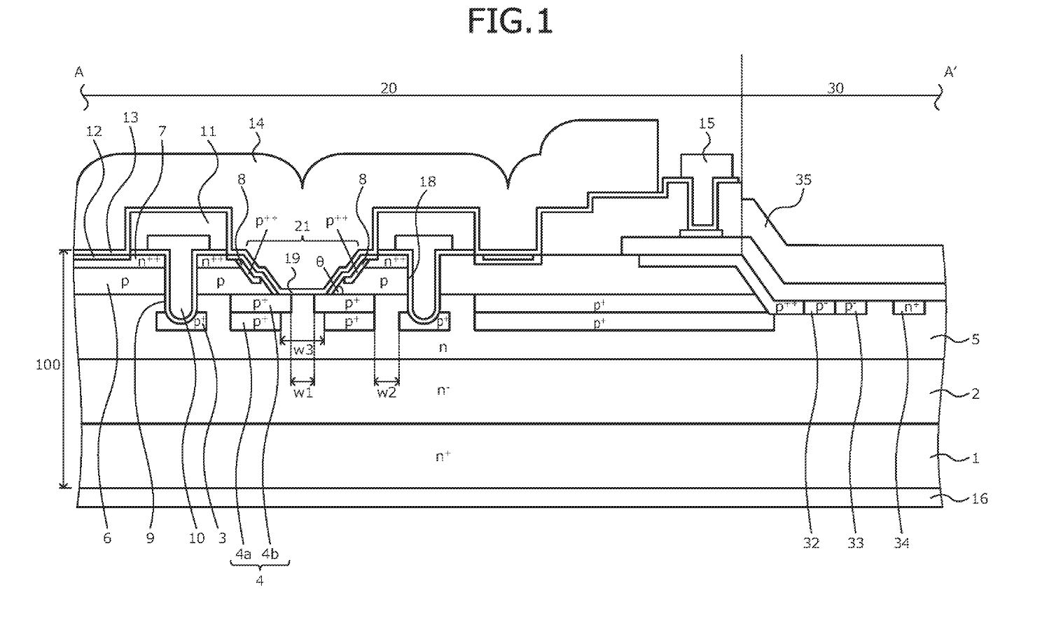

FIG. 1 is a cross-sectional view of a structure of the silicon carbide semiconductor device according to a first embodiment. As depicted in FIG. 1, the silicon carbide semiconductor device according to the first embodiment has a semiconductor base (hereinafter, silicon carbide base (semiconductor chip)) 100 containing silicon carbide and including an active region 20 and an edge termination region 30 surrounding a periphery of the active region 20. The active region 20 is a region through which current flows in an ON state. The edge termination region 30 is a region that mitigates electric field at a base front surface side of a drift region and sustains breakdown voltage.

The silicon carbide base 100 is formed by sequentially forming silicon carbide layers constituting an n⁻-type drift layer 2 and a p-type base layer (second semiconductor layer of a second conductivity type) 6, by epitaxial growth on an n⁺-type supporting substrate (hereinafter, n⁺-type silicon carbide substrate (semiconductor substrate of the first conductivity type)) 1 containing silicon carbide. A MOS gate is configured by the p-type base layer 6, an n⁺⁺-type source region (first semiconductor region of the first conductivity type) 7, a p⁺⁺-type contact region 8, a trench 18, a gate insulating film 9, and a gate electrode 10. More specifically, in a surface layer on a source side (side facing toward a source electrode 12) of the n⁻-type drift layer 2, an n-type region 5 (first semiconductor layer of the first conductivity type) is provided so as to contact the p-type base layer 6. The n-type region 5 is a so-called a current spreading layer (CSL) that reduces carrier spreading resistance. The n-type region 5, for example, is provided uniformly along a direction (hereinafter, lateral direction) parallel to the base front surface (front surface of the silicon carbide base 100).

In the n-type region 5, a first p⁺-type region (second semiconductor region of the second conductivity type) 3 and a second p⁺-type region (third semiconductor region of the second conductivity type) 4 are each selectively provided. Each second p⁺-type region 4 is constituted by a lower second V-type region 4a and an upper second p⁺-type region 4b. The first p⁺-type region 3 is provided so as to be in contact with a bottom of the trench 18. The first p⁺-type region 3 is provided from a position that from the base front surface, is deeper than an interface of the p-type base layer 6 and the n-type region 5, the p⁺-type region 3 being provided at a depth not reaching an interface of the n-type region 5 and the n⁻-type drift layer 2. Provision of the first p⁺-type region 3 enables formation of a pn junction near the bottom of the trench 18, between the first p⁺-type region 3 and the n-type region 5. An impurity concentration of the first p⁺-type region 3 is higher than an impurity concentration of the p-type base layer 6.

Further, a width of the first p⁺-type region 3 is wider than a width of the trench 18. The bottom of the trench 18 may reach the first p⁺-type region 3, or may be positioned in the n-type region 5 between the p-type base layer 6 and the p⁺-type region 3, without contacting the p⁺-type region 3. The lower second p⁺-type region 4a is selectively provided separated from the n⁻-type drift layer 2 and in contact with the upper second p⁺-type region 4b. The first p⁺-type region 3 and the second p⁺-type region 4 are doped with, for example, aluminum (Al).

In the p-type base layer 6, the n⁺⁺-type source region 7 and the p⁺⁺-type contact region 8 are selectively provided to be in contact with each other. A depth of the p⁺⁺-type contact region 8, for example, may be the same as or deeper than a depth of the n⁺⁺-type source region 7.

The trench 18 penetrates the n⁺⁺-type source region 7 and the p-type base layer 6 from the base front surface and reaches the n-type region 5 and the first p⁺-type region 3. In the trench 18, the gate insulating film 9 is provided along a side wall of the trench 18, and the gate electrode 10 is provided on the gate insulating film 9. A source-side end of the gate electrode 10 may or may not protrude outwardly from the base front surface. The gate electrode 10 is connected to a gate pad at a non-depicted part. An interlayer insulating film 11 is provided on the base front surface so as to cover the gate electrode 10 embedded in the trench 18.

The source electrode (first electrode) 12 is in contact with the n⁺⁺-type source region 7 and the p⁺⁺-type contact region 8 via a contact hole opened in the interlayer insulating film 11 and is electrically insulated from the gate electrode 10 by the interlayer insulating film 11. Between the source electrode 12 and the interlayer insulating film 11, for example, a barrier metal may be provided that prevents diffusion of metal atoms from the source electrode 12 toward the gate electrode 10. A source electrode pad 14 is provided on the source electrode 12. A drain electrode (second electrode) 16 is provided on a rear surface (rear surface of the n⁺-type silicon carbide substrate 1 constituting the n⁺-type drain region) of the silicon carbide base 100.

Further, a metal film 13 is provided at the base front surface in the active region 20 overall so as to cover the interlayer insulating film 11 and the source electrode 12. Although the metal film 13 may be titanium (Ti) to block intrusion of hydrogen (H₂) into the interlayer insulating film 11, the metal film 13 may be another metal that forms a Schottky contact with SiC such as nickel (Ni), tungsten (W), molybdenum (Mo), gold (Au), platinum (Pt), or the like.

Between the trench 18 and a trench 18 adjacent thereto, a recess 21 is provided. A bottom surface of the recess 21 reaches the n-type region 5. The bottom surface and a side surface (incline) of the recess 21 form an angle θ that is 15° to 80°. Unlike the trench 18 that is formed substantially vertically (90°) in a depth direction, the angle θ of the recess 21 is shallow, facilitating favorable metal coverage at the recess 21.

Further, at the bottom surface of the recess 21, the metal film 13 forms a Schottky contact with the n-type region 5 and configures a SBD part 19 built into the silicon carbide semiconductor device. The SBD part 19 is connected to the source electrode 12 and the source electrode pad 14, and is a built-in SBD. The SBD part 19 has the source electrode pad 14, which is a common upper electrode common to the source electrode 12. Therefore, a separate Schottky electrode need not be provided. Further, at the side surface of the recess 21, the n⁺⁺-type source region 7 and the p⁺⁺-type contact region 8 may be provided. Provision of the n⁺⁺-type source region 7 and the p⁺⁺-type contact region 8 at an inclined surface enables a mathematical area of contact with the source electrode 12 to be increased.

Here, configuration may be such that a distance w1 between the upper second p⁺-type regions 4b positioned beneath the recess 21 may be about equal to a distance w2 between the lower second p⁺-type region 4a and the first p⁺-type region 3. A reason for this is that breakdown voltage of the semiconductor device is determined by a distance between p-type regions and therefore, when the distance w1 and the distance w2 differ, the breakdown voltage may be different at parts of the semiconductor device.

A distance w3 between the lower second p⁺-type regions 4a positioned beneath the recess 21 may be greater than the distance w1. Since breakdown voltage of the active region 20 is determined by the greater of the distance w3 and the distance w2, and the breakdown voltage decreases with increasing distance and ON resistance decreases with increasing distance, configuration may be such that the distance w3 and the distance w2 are equal.

In a periphery of the active region 20 near the edge termination region 30, a gate runner 15 connected to a gate pad electrode is arranged. The p-type base layer 6 is removed from the entire edge termination region 30 and in the edge termination region 30, a step 35 (recess) is formed at the front surface of the silicon carbide base 100, making the front surface of the silicon carbide base 100 lower in the edge termination region 30 than in the active region 20, and exposing the n⁻-type drift layer 2 at a bottom surface of the step 35. Further, in the edge termination region 30, a JTE structure is provided in which plural p⁻-type low-concentration regions (here, two regions including, from the active region 20, a p⁻-type first JTE structure 32 and a p⁻⁻-type second JTE structure 33) are arranged adjacently and the closer a p⁻-type low-concentration region is arranged to an outer side (chip end), the lower an impurity concentration of the p⁻-type low-concentration region is. Further, an n⁺-type semiconductor region 34 that functions as a channel stopper is provided at an outer side (toward the chip end) of the JTE structure.

The first JTE structure 32 and the second JTE structure 33 are each selectively provided in the n⁻-type drift layer 2. The first JTE structure 32 is in contact with the p⁺⁺-type contact region 8 provided in the p-type base layer 6. These JTE structures configure a breakdown voltage structure.

In FIG. 1, although only 2 trench MOS gate structures are depicted, further MOS gate (insulated gate using a metal-oxide film-semiconductor) structures of a trench gate structure may be arranged.

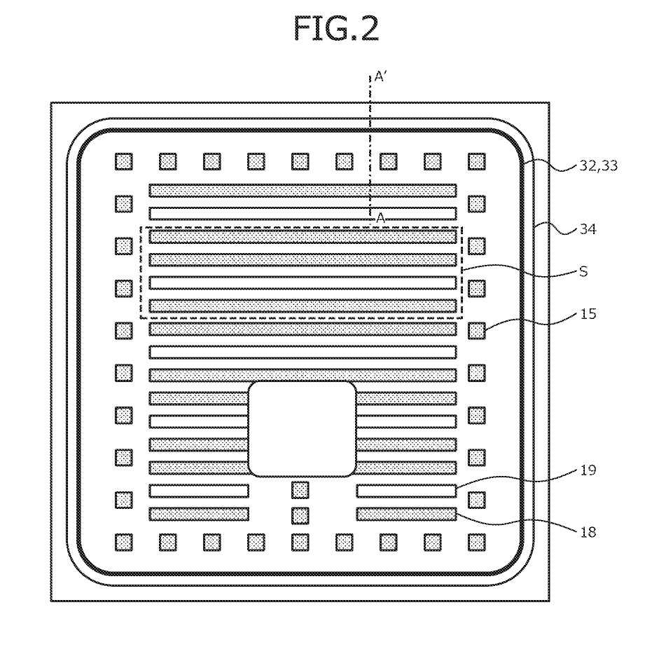

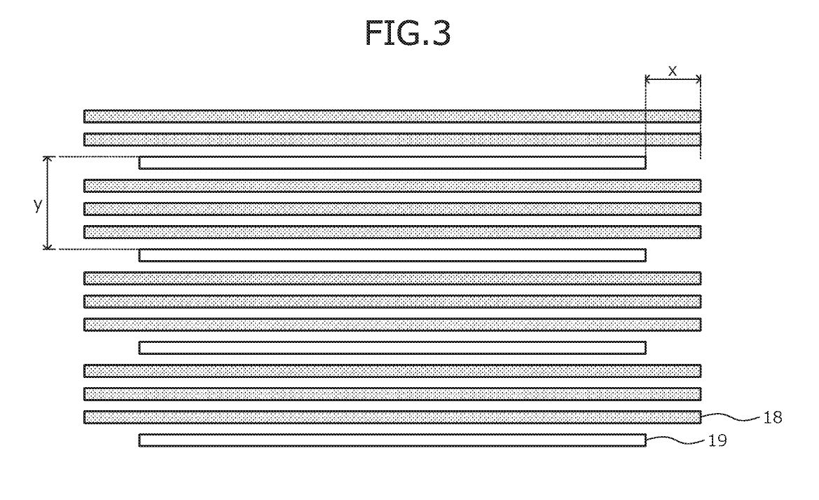

FIG. 2 is a top view of the structure of the silicon carbide semiconductor device according to the first embodiment. FIG. 1 is a cross-sectional view at cutting line A-A′ in FIG. 2. As depicted in FIG. 2, the SBD part 19 is arranged parallel to the trench 18. FIG. 3 is an enlarged view of a region S depicted in FIG. 2 of the silicon carbide semiconductor device according to the first embodiment. As depicted in FIG. 3, an end of the trench 18 is extends outwardly (toward the edge termination region 30) beyond an end of the SBD part 19 by a distance x. Configuration may be such that the distance x is, for example, shorter than 0.5 μm. Further, as depicted in FIG. 3, the SBD part 19 is arranged between sets of plural (in FIG. 3, three) trenches 18. An interval y between the SBD parts 19 may be short. A reason for this is that when the interval y is long, the number of the SBD parts 19 decreases and current that flows through the SBD part 19 at the time of flyback decreases while a majority of current flows through a parasitic pn diode, whereby bipolar degradation is likely to occur.

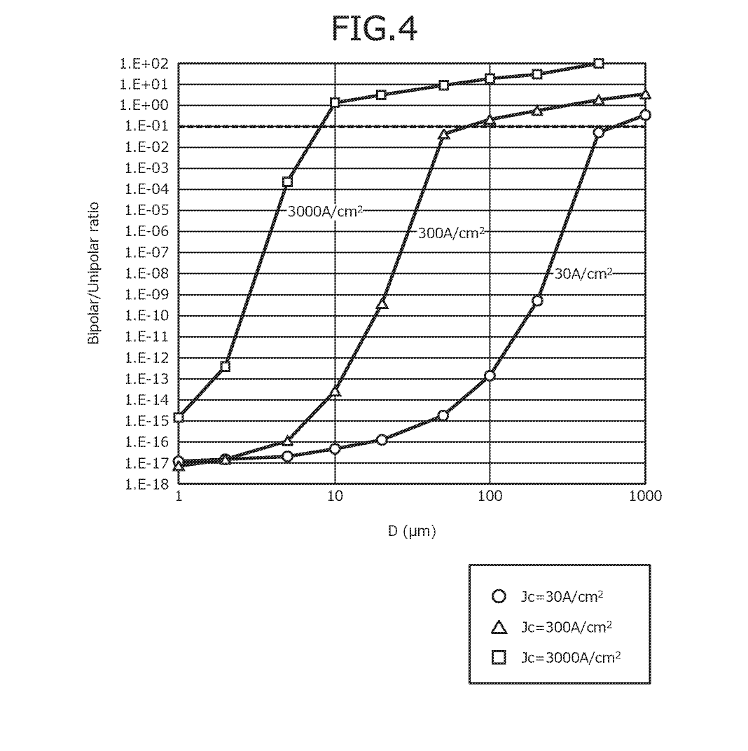

Here, a value of the interval y between the SBD parts 19 is described. FIG. 4 is a graph depicting a relationship of SBD width and current ratio of the parasitic pn diode and the SBD in the silicon carbide semiconductor device according to the first embodiment. In FIG. 4, a horizontal axis is a distance D from the SBD part 19 to a MOS gate structure, the distance D being in units of μm. A vertical axis is a ratio (B/U) of the current flowing through the parasitic pn diode to the current flowing through the SBD part 19.

As depicted in FIG. 4, with respect to a rated current of 300 A/cm² for a SiC-MOSFET, measurement results were 3000 A/cm², which is 10 times the target guaranteed rated current for the SiC-MOSFET, and 30 A/cm². In the SiC-MOSFET, when B/U exceeds 1.0, characteristics change over time due to bipolar operation and therefore, configuration may be such that B/U is 1.0 or less. Therefore, when the rated current is 300 A/cm², the distance D may be 120 μm or less. Since the distance D is ½ or less of the interval y between the SBD parts 19, the interval y between the SBD parts 19 may be 240 μm or less.

Further, because current flowing through the parasitic pn diode decreases and temporal characteristics due to bipolar operation are suppressed, the distance D may be 80 μm or less. Therefore, the interval y between the SBD parts 19 may be 160 m or less.

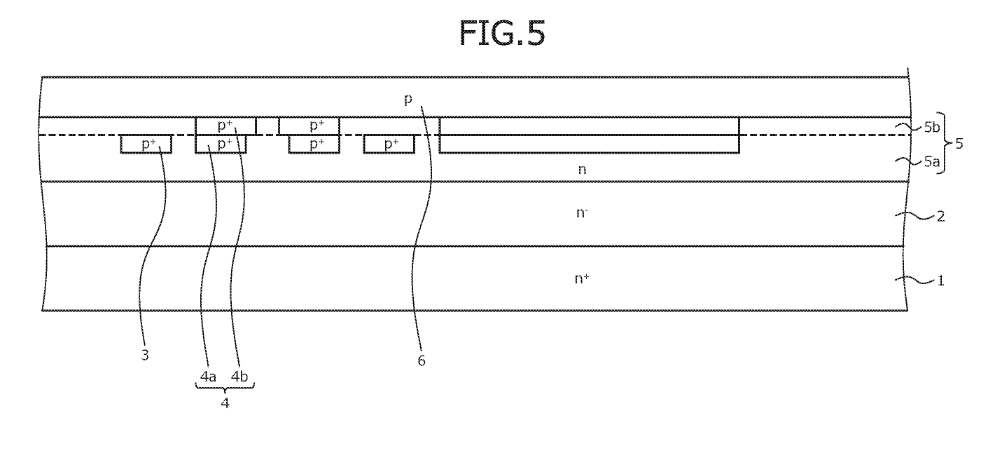

A method of manufacturing the silicon carbide semiconductor device according to the first embodiment will be described taking, as an example, a case in which a 3300V trench-type SiC-MOSFET is fabricated (manufactured). FIGS. 5, 6, and 7 are cross-sectional views of the silicon carbide semiconductor device according to the first embodiment during manufacture. First, for example, the silicon carbide single-crystal n⁺-type silicon carbide substrate (semiconductor wafer) 1 doped with an n-type impurity (dopant) such as nitrogen (N) so that an impurity concentration of the n⁺-type silicon carbide substrate 1 becomes 2.0×10¹⁹/cm³ is prepared. A front surface of the n⁺-type silicon carbide substrate 1 may be, for example, a (000-1) plane having an off angle of 4 degrees in a <11-20> direction. Next, on the front surface of the n⁻-type silicon carbide substrate 1, the n⁻-type drift layer 2 doped with an n-type impurity such as nitrogen so as to have an impurity concentration of, for example, 1.0×10¹⁶/cm³ is formed by epitaxial growth. The n⁻-type drift layer 2 has a thickness of, for example, 30 μm.

Next, on the n⁻-type drift layer 2, a lower n-type region 5a is formed by epitaxial growth. For example, conditions of the epitaxial growth for forming the lower n-type region 5a may be set so that an impurity concentration of the lower n-type region 5a becomes about 1×10¹⁷/cm³. The lower n-type region 5a is a part of the n-type region 5. Next, by photolithography and ion implantation of a p-type impurity, the first p⁺-type region 3 and the lower second p⁺-type region 4a are selectively formed in a surface layer of the lower n-type region 5a. An outermost lower second p⁺-type region 4a is formed to extend to the edge termination region 30. For example, a dose amount at the time of ion implantation for forming the first p⁺-type region 3 and the lower second p⁺-type region 4a may be set so that an impurity concentration thereof becomes about 5×10¹⁸/cm³.

Next, an upper n-type region 5b is formed on the lower n-type region 5a, the first p⁺-type region 3 and the lower second p⁺-type region 4a, by epitaxial growth. For example, conditions of the epitaxial growth for forming the upper n-type region 5b may be set so that an impurity concentration of the upper n-type region 5b becomes about the same as the impurity concentration of the lower n-type region 5a. The upper n-type region 5b is a part of the n-type region 5. The lower n-type region 5a and the upper n-type region 5b combined form the n-type region 5. Next, by photolithography and ion implantation of a p-type impurity, the upper second p⁺-type region 4b is selectively formed in a surface layer of the upper n-type region 5b. An outermost upper second p⁺-type region 4b is formed to extend to the edge termination region 30. For example, a dose amount at the time of ion implantation for forming upper second p⁺-type region 4b may be set so that an impurity concentration thereof becomes about the same as that of the lower second p⁺-type region 4a.

Next, the p-type base layer 6 is formed on the upper n-type region 5b and the upper second p⁺-type region 4b, by epitaxial growth. For example, conditions of the epitaxial growth for forming the p-type base layer 6 may be set so that an impurity concentration of the p-type base layer 6 becomes about 4×10¹⁷/cm³. The state up to here is depicted in FIG. 5.

Next, by photolithography and etching, the step 35 is formed at a surface of the p-type base layer 6 in the edge termination region 30, and the p-type base layer 6 and a part of the n-type region 5 are removed, exposing the n-type region 5. Concurrently, the recess 21 is formed at the surface of p-type base layer 6 in the active region 20, and a part of the p-type base layer 6 is removed, exposing the n-type region 5.

Next, by photolithography and ion implantation of an n-type impurity, the n⁺⁺-type source region 7 is selectively formed in a surface layer of the p-type base layer 6. For example, a dose amount at the time of ion implantation for forming the n⁺⁺-type source region 7 may be set so that an impurity concentration thereof becomes about 3×10²⁰/cm³. By the processes up to here, the silicon carbide base 100 is fabricated by sequential stacking of the n⁻-type drift layer 2 and the p-type base layer 6 in stated order on the front surface of the n⁺-type silicon carbide substrate 1.

Next, by photolithography and ion implantation of a p-type impurity, the p⁺⁺-type contact region 8 is selectively formed in the surface layers of the p-type base layer 6 and the n⁺⁺-type region source 7. For example, a dose amount at the time of ion implantation for forming the p⁺⁺-type contact region 8 may be set so that an impurity concentration thereof becomes about 3×10²⁰/cm³.

Next, by photolithography and ion implantation of a p-type impurity, the first JTE structure 32 and the second JTE structure 33 are selectively formed in a surface layer of the n-type region 5 in the edge termination region 30. For example, a dose amount at the time of ion implantation for forming the first JTE structure 32 and the second JTE structure 33 may be set so that impurity concentrations thereof are about 3×10¹⁷/cm³ and 6×10¹⁷/cm³, respectively.

Next, by photolithography and ion implantation of an n-type impurity, the n⁺-type semiconductor region 34 is selectively formed in the surface layer of the n-type region 5 in the edge termination region 30. For example, a dose amount at the time of ion implantation for forming the n⁺-type semiconductor region 34 may be set so that an impurity concentration thereof becomes about 3×10²⁰/cm³.

Next, heat treatment (annealing) is performed and, for example, the first p⁺-type region 3, the n⁺⁺-type source region 7, the p⁺⁺-type contact region 8, the first JTE structure 32, the second JTE structure 33, and the n⁺-type semiconductor region 34 are activated. A temperature of the heat treatment may be, for example, about 1700 degrees C. A period of the heat treatment may be, for example, about 2 minutes. Ion implanted regions may be collectively activated by a single session of the heat treatment as described above, or may be activated by heat treatment performed each time ion implantation is performed.

Next, at a surface (i.e., surfaces of the n⁺⁺-type source region 7 and the p⁺⁺-type contact region 8) of the p-type base layer 6, the trench 18 is formed by photolithography and etching. The trench 18 penetrates the n⁺⁺-type source region 7 and the p-type base layer 6, and reaches the n-type region 5. The bottom of the trench 18 reaches the first p⁺-type region 3.

Next, along the surfaces of the n⁺⁺-type source region 7 and the p⁺⁺-type contact region 8 and side walls and the bottom of the trench 18, the gate insulating film 9 containing silicon dioxide (SiO₂) is formed. The gate insulating film 9 may be formed by thermal oxidation by heat treatment at a temperature of about 1000 degrees C. in an oxygen atmosphere. Further, the gate insulating film 9 may be formed by a deposition method by a chemical reaction such as that for a high temperature oxide (HTO).

Next, on the gate insulating film 9, a polycrystalline silicon layer doped with, for example, phosphorus atoms (P) is formed. The polycrystalline silicon layer is formed so as to be embedded in the trench 18. The polycrystalline silicon layer is patterned to remain in the trench 18, whereby the gate electrode 10 is formed. A part of the gate electrode 10 may protrude upwardly (toward the interlayer insulating film 11) from the trench 18, toward the source electrode pad 14.

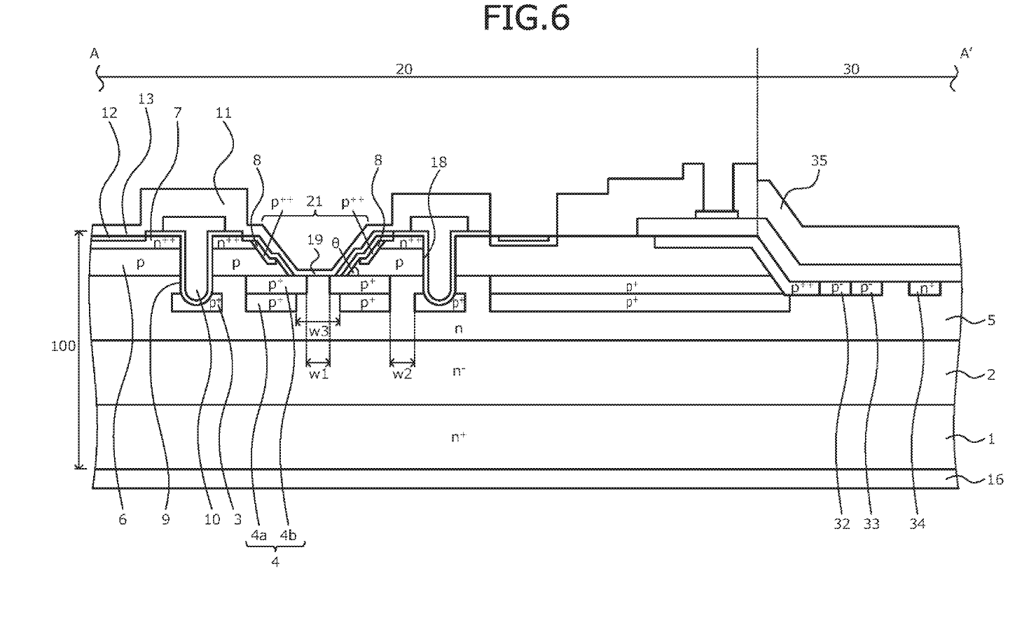

Next, for example, a phosphorus glass (PSG), SiO₂, etc. is deposited to a thickness of about 1 μm and so as to cover the gate insulating film 9, the gate electrode 10 and the recess 21, whereby the interlayer insulating film 11 is formed. The state up to here is depicted in FIG. 6.

Next, the interlayer insulating film 11 and the gate insulating film 9 are patterned and selectively removed, whereby a contact hole is formed, exposing the n⁺⁺-type source region 7 and the p⁺⁺-type contact region 8. Thereafter, heat treatment (reflow) is performed and the interlayer insulating film 11 is planarized.

Next, in the contact hole and on the interlayer insulating film 11, a conductive film constituting the source electrode 12 is formed. The conductive film is selectively removed, leaving the source electrode 12, for example, only in the contact hole.

Next, on the rear surface (the rear surface of the n⁺-type silicon carbide substrate 1) of the silicon carbide base 100, the drain electrode 16 constituted by, for example, a nickel (Ni) film, is formed. Thereafter, heat treatment at a temperature of, for example, about 1000 degrees C. is performed, forming an ohmic junction of the n⁺-type silicon carbide substrate 1 and the drain electrode 16.

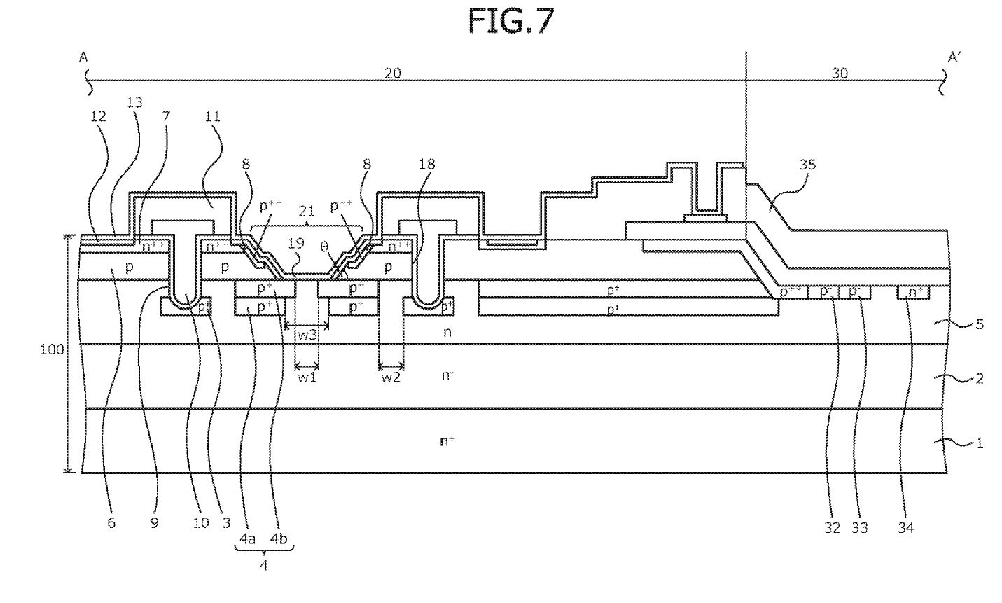

Next, the interlayer insulating film 11 and the gate insulating film 9 are patterned and selectively removed, whereby the n-type region 5 at the bottom surface of the recess 21 is exposed. Next, the metal film 13 containing, for example, Ti, is formed on an entire front surface of the p-type base layer 6. The state up to here is depicted in FIG. 7. Next, for example, heat treatment (annealing) in a nitrogen (N₂) atmosphere of a temperature of about 500 degrees C. or less is performed, whereby the SBD part 19 is formed having a Schottky contact of the metal film 13 and the n-type region 5 at the bottom surface of the recess 21.

Next, for example, by a sputtering method, for example, an aluminum film is formed to have a thickness of, for example, about 5 μm and is formed to cover the source electrode 12, the interlayer insulating film 11, and the SBD part 19. Thereafter, the aluminum film is selectively removed so as to remain covering the active region 20, whereby the source electrode pad 14 is formed.

Next, on a surface of the drain electrode 16, for example, titanium, nickel, and gold are sequentially deposited in stated order, whereby a drain electrode pad is formed. By the manner described, the semiconductor device depicted in FIG. 1 is completed.

As described, in the first embodiment, the SBD part is provided in a recess of the active region. The angle θ formed by a side surface and a bottom surface of the recess is 15° to 80°, and since the angle θ is shallow, favorable metal coverage thereon is facilitated and an occurrence of defects decreases. Equipment such as that for metal CVD introduced as a measure for metal coverage on the trench is unnecessary. Further, the recess may be formed concurrently when the edge termination region is formed and therefore, additional workload for formation of the recess is unnecessary and existing manufacturing processes for a trench-type MOSFET may be utilized as is without increases in fabrication cost. Further, the SBD part is formed in the recess and therefore, to reduce surface roughness, a carbon coat layer called a semiconductor-base carbon cap may be formed.

Further, the n⁺⁺-type source region and the p⁺⁺-type contact region are provided at a side wall of the recess, whereby the mathematical area of contact with the source electrode may be increased. Further, the SBD part is provided in a recess in the active region and therefore, the source electrode and the SBD part may be connected by a single Al electrode and without a need for a process of patterning a Schottky electrode in the active region, fabrication costs may be reduced. Further, in the MOS gate structure, since Ti for hydrogen blocking and Ti of the SBD part are formed in the same layer, fabrication costs do not increase.

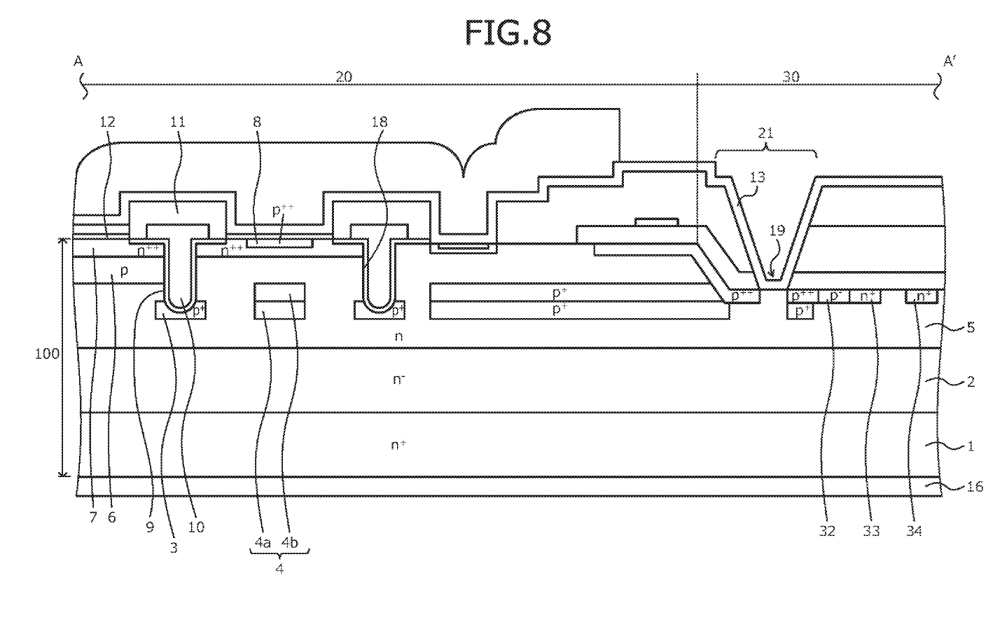

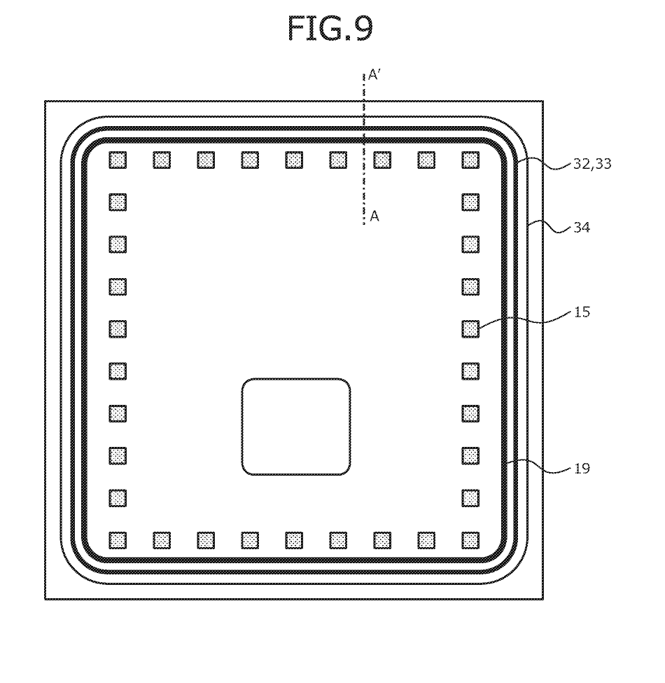

A structure of the semiconductor device according to a second embodiment will be described. FIG. 8 is a cross-sectional view of a structure of the silicon carbide semiconductor device according to the second embodiment. Further, FIG. 9 is a top view of the structure of the silicon carbide semiconductor device according to the second embodiment.

As depicted in FIGS. 8 and 9, the semiconductor device according to the second embodiment differs from the semiconductor device according to the first embodiment in that the recess 21 is provided on an outer side of the gate runner 15, in the edge termination region 30. Therefore, as depicted in FIG. 9, the SBD part 19 is formed so as to surround the outer side of the gate runner 15.

Further, the SBD part 19 provided in the edge termination region 30 may not sufficiently reduced the current flowing through the parasitic pn diode and therefore, a SBD has to be provided in the active region 20 as well. This SBD may be a planar type, a trench type of a related art, or the recess type of the first embodiment. Even with a planar type or a trench type of a related art, since the SBD part 19 in the edge termination region 30 is provided, the SBDs of the active region 20 may be reduced as compared to a related art and the workload for forming a planar type or a trench type of a related art may be reduced.

Further, in the second embodiment, a lower second p⁺-type region is provided beneath the p⁺⁺-type contact region 8 that is extended to the edge termination region 30. This is to make the distance between the p⁺-type regions beneath the SBD part 19 consistent with distances between p⁺-type regions in the active region 20 and maintain the breakdown voltage.

A method of manufacturing the semiconductor device according to the second embodiment will be described taking, as an example, a case in which a 3300V trench-type SiC-MOSFET is fabricated. The method of manufacturing the semiconductor device according to the second embodiment, for example, is such that in the method of manufacturing the semiconductor device according to the first embodiment, the recess 21 is formed in the edge termination region 30. More specifically, first, similarly to the first embodiment, on the front surface of the n⁺-type silicon carbide substrate (semiconductor wafer) 1 constituting an n⁺-type drain layer, the n⁻-type drift layer 2 is formed by epitaxial growth. Similarly to the first embodiment, processes of forming the step 35 at the surface of the p-type base layer 6 in the edge termination region 30, and removing the p-type base layer 6, exposing the n-type region 5 are performed.

Next, similarly to the first embodiment, the process of selectively forming the p⁺⁺-type contact region 8 in the surface layers of the p-type base layer 6 and the n-type region 5, to the process of selectively removing the conductive film, leaving the source electrode 12, for example, only in the contact hole are performed.

Next, the recess 21 is formed at the surfaces of the interlayer insulating film 11 and the gate insulating film 9 in the edge termination region 30, exposing the n-type region 5. Thereafter, similarly to the first embodiment, the process of forming on the entire front surface of the p-type base layer 6, the metal film 13 containing, for example, Ti and subsequent processes are performed, whereby the semiconductor device depicted in FIG. 7 is completed. Here, the metal film 13 is formed on the entire surface in the active region 20 and the edge termination region 30.

As described, according to the second embodiment, the SBD part is provided in a recess in the edge termination region. Similarly to the first embodiment, the angle θ formed by a side surface and the bottom of the recess is 15° to 80° and since the angle θ is shallow, favorable metal coverage thereon is facilitated and the occurrence of defects decreases.

Further, according to the second embodiment, the SBD part may be provided in the edge termination region without adding new processes. Provision of the SBD part in the edge termination region, enables fewer SBDs to be provided in active region, whereby a greater number of the MOS gate structures may be formed in the active region. Further, an outer peripheral pn junction may be protected by the recess in the edge termination region.

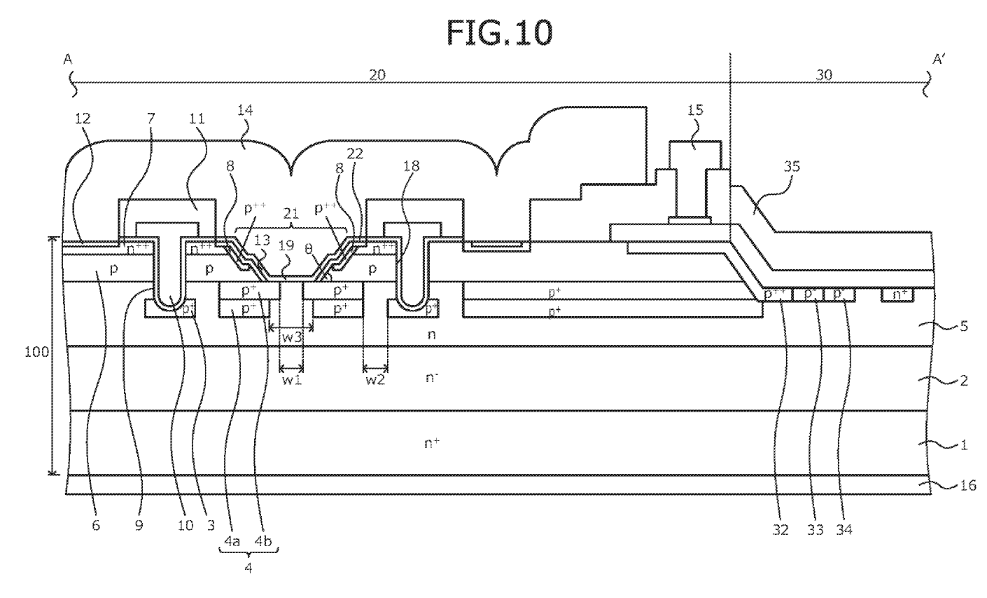

A structure of the semiconductor device according to a third embodiment will be described. FIG. 10 is a cross-sectional view of a structure of the silicon carbide semiconductor device according to the third embodiment. As depicted in FIG. 10, the semiconductor device according to the third embodiment differs from the semiconductor device according to the first embodiment in that the metal film 13 forming a Schottky contact is formed only at a periphery of the SBD part 19. Therefore, in the MOS gate structure, for example, a nickel silicide layer 22 is provided at a part of a side surface of the recess 21 without providing the metal film 13 on the surface of the interlayer insulating film 11 or on the surface of the gate insulating film 9.

Since the metal film 13 is formed at only a periphery of the SBD part 19, a metal other than Ti may be used for the metal film 13. For example, tungsten (W), which has a high resistance, may be used.

A method of manufacturing the semiconductor device according to the third embodiment will be described taking, as an example, a case in which a 3300V trench-type SiC-MOSFET is fabricated. The method of manufacturing the semiconductor device according to the third embodiment, for example, is such that in the method of manufacturing the semiconductor device according to the first embodiment, the metal film 13 is formed at a part of a side surface and the bottom of the recess 21, and a nickel film is formed at a part of the side surface, above (toward the source electrode 12) the metal film 13 and the nickel silicide layer 22 is formed by heat treatment.

More specifically, first, similarly to the first embodiment, on the front surface of the n⁺-type silicon carbide substrate (semiconductor wafer) 1 constituting an n⁺-type drain layer, the n⁻-type drift layer 2 is formed by epitaxial growth. Next, similarly to the first embodiment, the processes up to exposing the n-type region 5 at the bottom surface of the recess 21 by patterning and selectively removing the interlayer insulating film 11 and the gate insulating film 9 are performed.

Next, in the recess 21, on the side surface thereof on which the metal film 13 is to be provided, the nickel film is formed. A silicon carbide semiconductor part (the n⁺⁺-type source region 7 and the p⁺⁺-type contact region 8) and the nickel film are caused to react by sintering (heat treatment), whereby the nickel silicide layer 22 is formed, thereby forming an ohmic contact with the silicon carbide semiconductor part.

Next, in the recess 21, the metal film 13 containing, for example, Ti is formed at the bottom surface of the recess 21 and at a part of the side surface in contact with the bottom surface. Next, for example, heat treatment (annealing) is performed in a nitrogen (N₂) atmosphere of a temperature of 500 degrees C. or less, whereby the SBD part 19 having a Schottky contact of the metal film 13 and the n-type region 5 at bottom surface of the recess 21 is formed.

Thereafter, similarly to the first embodiment, the process of forming the drain electrode 16 and subsequent processes are performed, whereby the semiconductor device depicted in FIG. 8 is completed.

As described, according to the third embodiment, effects similar to those of the first embodiment are obtained. Further, in the third embodiment, the metal film constituting a Schottky metal is formed only at the BD part and is not formed at other regions of the MOS gate structure. Therefore, a metal other than Ti may be used for the metal film. For example, tungsten, which has a high resistance, may be used.

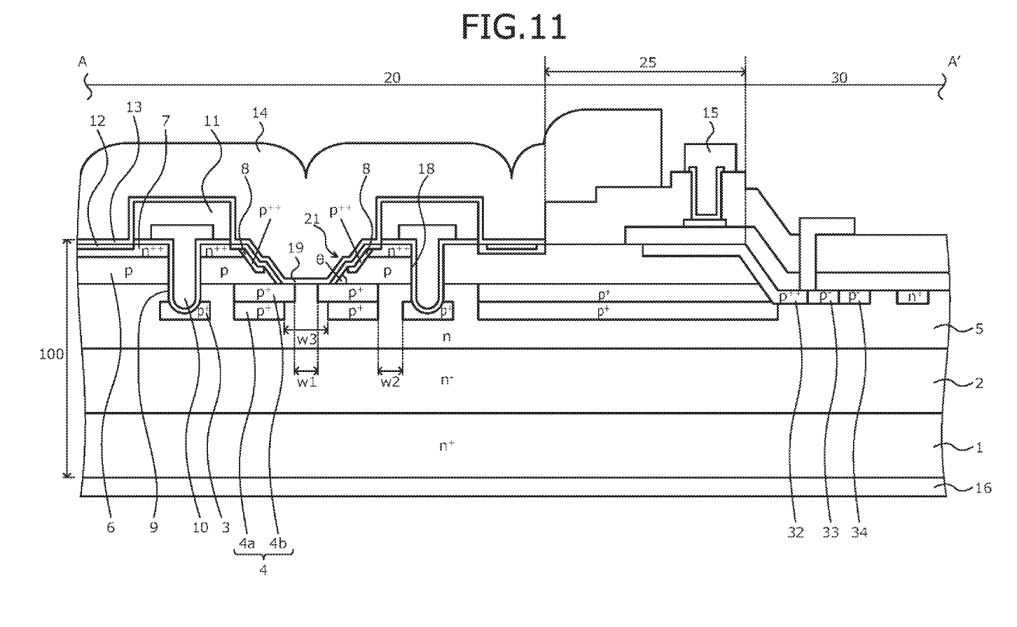

A structure of the semiconductor device according to a fourth embodiment will be described. FIG. 11 is a cross-sectional view of a structure of the silicon carbide semiconductor device according to the fourth embodiment. As depicted in FIG. 11, the semiconductor device according to the fourth embodiment differs from the semiconductor device according to the first embodiment in that the metal film 13 forming a Schottky contact is provided in a termination region 25 of the active region 20. The termination region 25 is a region between a region in which the MOS gate structure in the active region 20 is provided and the edge termination region 30.

A method of manufacturing the silicon carbide semiconductor device according to the fourth embodiment will be described taking, as an example, a case in which a 3300V trench-type SiC-MOSFET is fabricated. The method of manufacturing the semiconductor device according to the fourth embodiment, for example, is such that in the method of manufacturing the semiconductor device according to the first embodiment, after the metal film 13 is formed on the entire front surface of the p-type base layer 6, the metal film 13 in the termination region 25 is removed.

More specifically, first, similarly to the first embodiment, the metal film 13 containing, for example, Ti is formed on the entire front surface of the p-type base layer 6. Next, the metal film 13 is patterned and selectively removed, exposing SiO₂ (the interlayer insulating film 11) in the termination region 25.

Thereafter, similarly to the first embodiment, the process of forming the SBD part 19 having a Schottky contact to the process of forming the drain electrode 16 and subsequent processes are performed, whereby the semiconductor device depicted in FIG. 11 is completed.

As described, according to the fourth embodiment, no metal film constituting a Schottky metal is formed in the termination region. Therefore, Al having good adhesion with SiO₂ is brought into contact with SiO₂. In the fourth embodiment, the Ti film may be patterned before formation of the Al film, whereby wet etching may be performed without concern side etching of the Ti film. Therefore, while a large etching amount is desirable so that Ti does not remain in the termination region, etching period adjustment and an inspection process, which were necessary since side etching beneath the Al film progresses, become unnecessary.

Further, in the first to fourth embodiments, a side surface of the recess 21 is formed having two steps. However, the number of steps may be one, or more than two.

In the embodiments of the present invention, various modifications within a scope not departing from the spirit of the invention are possible. For example, dimensions, impurity concentrations, etc. of regions may be set according to required specifications. Further, in the embodiments, although a MOSFET has been described as an example, without limitation hereto, wide application to various silicon carbide semiconductor devices that conduct and interrupt current by gate driving control based on a predetermined gate threshold voltage is possible. As a silicon carbide semiconductor device under gate driving control, for example, an insulated gate bipolar transistor (IGBT) may be given as an example. Further, in the described embodiments, although a case in which silicon carbide is used as a wide bandgap semiconductor material has been described as an example, a wide bandgap semiconductor material other than silicon carbide, such as, for example, gallium nitride (GaN) or the like is applicable. In the embodiments, although the first conductivity type is assumed to be an n-type and the second conductivity type is assumed to be a p-type, the present invention is similarly implemented when the first conductivity type is a p-type and the second conductivity type is an n-type. In this case, in an n-type base region, by ion implantation, an n⁺-type high-concentration ion implantation region having an impurity concentration profile that is the same as the p-type impurity concentration profile of FIG. 2 is formed.

According to the embodiments of the present invention, the SBD part is provided in a recess in the active region. The angle θ formed by a side surface and the bottom of the recess is 15° to 80° and since the angle θ is shallow, favorable metal coverage thereon is facilitated and the occurrence of defects decreases. Equipment such as that for metal chemical vapor deposition (CVD) introduced as a measure for metal coverage on the trench is unnecessary. Further, the recess may be formed concurrently when the edge termination region is formed and therefore, additional workload for formation of the recess is unnecessary and existing manufacturing processes for a trench-type MOSFET may be utilized as is without increases in fabrication cost. Further, the SBD part is formed in the recess and therefore, to reduce surface roughness, a carbon coat layer called a semiconductor-base carbon cap may be formed.

Further, the n⁺⁺-type source region and the p⁺⁺-type contact region are provided at a side wall of the recess, whereby the mathematical area of contact with the source electrode may be increased. Further, the SBD part is provided in a recess in the active region and therefore, the source electrode and the SBD part may be connected by a single Al electrode and without a need for a process of patterning a Schottky electrode in the active region, fabrication costs may be reduced. Further, in the MOS gate structure, since Ti for hydrogen blocking and Ti of the SBD part are formed in the same layer, fabrication costs do not increase.

The silicon carbide semiconductor device and method of manufacturing a silicon carbide semiconductor device according to the embodiments of the present invention achieve an effect in that bipolar operation at the time of flyback is suppressed by a built-in SBD and fabrication of the built-in SBD is facilitated.

As described, the silicon carbide semiconductor device and the method of manufacturing a silicon carbide semiconductor device according to the embodiments of the present invention are useful for power semiconductor devices used in power conversion equipment and power source devices such as in various industrial machines. The silicon carbide semiconductor device and the method of manufacturing a silicon carbide semiconductor device are particularly suitable for silicon carbide semiconductor devices having a trench gate structure.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate of a first conductivity type, having a front surface and a rear surface;
a first semiconductor layer of the first conductivity type provided on a front surface side of the semiconductor substrate, and having a first side and the second side, the second side being opposite to the first side and facing the front surface of the semiconductor substrate;
a second semiconductor layer of a second conductivity type provided on the first side of the first semiconductor layer;
a first semiconductor region of the first conductivity type selectively provided in the second semiconductor layer, an impurity concentration of the first semiconductor region being higher than an impurity concentration of the semiconductor substrate;
a gate insulating film;
a plurality of gate electrodes respectively provided in a plurality of trenches, via the gate insulating film, each of the plurality of trenches penetrating the first semiconductor region and the second semiconductor layer, and reaching the first semiconductor layer;
a first electrode in contact with the first semiconductor region and the second semiconductor layer;
a second electrode provided on the rear surface of the semiconductor substrate;
a recess provided between two adjacent ones of the trenches, the recess having a side surface and a bottom surface that form an angle in a range of 15° to 80°; and
a metal electrode at the bottom surface of the recess and forming a Schottky contact with the first semiconductor layer.

2. The silicon carbide semiconductor device according to claim 1, further comprising:
a plurality of second semiconductor regions of the second conductivity type selectively provided in the first semiconductor layer, each second semiconductor region being in contact with a respective bottom of one of the trenches, an impurity concentration of each said second semiconductor region being higher than an impurity concentration of the second semiconductor layer; and
a plurality of third semiconductor regions of the second conductivity type selectively provided in the first semiconductor layer, an impurity concentration of each of the third semiconductor regions being higher than the impurity concentration of the second semiconductor layer, wherein
a width of the metal electrode at the bottom surface of the recess is approximately equal to a distance between one of the second semiconductor regions and one of the third semiconductor regions that is closest to the one of the second semiconductor regions in a plan view.

3. The silicon carbide semiconductor device according to claim 1, further comprising:
a plurality of second semiconductor regions of the second conductivity type selectively provided in the first semiconductor layer, each second semiconductor region being in contact with a respective bottom of one of the trenches, an impurity concentration of each said second semiconductor region being higher than an impurity concentration of the second semiconductor layer; and
a plurality of third semiconductor regions of the second conductivity type selectively provided in the first semiconductor layer, an impurity concentration of each of the third semiconductor regions being higher than the impurity concentration of the second semiconductor layer, wherein
a width of two adjacent ones of the third semiconductor regions is approximately equal to a distance between one of the second semiconductor regions and one of the third semiconductor regions that is closest to the one of the second semiconductor regions in a plan view.

4. The silicon carbide semiconductor device according to claim 1, further comprising:
an active region provided at the semiconductor substrate, and through which a main current flows; and
a termination region surrounding a periphery of the active region, wherein
the trenches respectively extend in a first direction toward the termination region and being parallel to each other in the active region,
the recess includes at least two recesses,
the metal electrode at the bottom surface of the recess includes at least two metal electrodes, each of which is disposed at a respective bottom surface of one of the recesses, and extends in a direction parallel to the trenches in the active region,
each said trench has a length at least 0.5 μm longer at both ends of each said trench than a length of the metal electrode in the first direction, and
a distance between two adjacent ones of the metal electrodes, each of which is disposed at the respective bottom surface of one of the recesses, in a second direction perpendicular to the first direction is less than 240 μm.

5. The silicon carbide semiconductor device according to claim 4, wherein
the distance between the two adjacent ones of the metal electrodes is less than 160 μm.

6. The silicon carbide semiconductor device according to claim 1, further comprising a common upper electrode electrically connected to both of the metal electrode and the first electrode.

7. The silicon carbide semiconductor device according to claim 4, further comprising a metal film entirely covering the active region, wherein
the metal film disposed in each one of the recesses constitutes a respective one of the metal electrodes.

8. The silicon carbide semiconductor device according to claim 4, further comprising
a metal-oxide-semiconductor (MOS) gate structure including the gate electrode and the gate insulating film, and
a metal film covering only a region in which the MOS gate structure is formed, the metal film disposed in each one of the recesses constituting a respective one of the metal electrodes.

9. The silicon carbide semiconductor device according to claim 1, further comprising:
an active region provided at the semiconductor substrate, and through which a main current flows; and
a termination region surrounding a periphery of the active region, wherein
the metal electrode is provided in the termination region so as to surround the active region.

10. The silicon carbide semiconductor device according to claim 1, wherein the metal electrode is made of a metal film that is provided only at the bottom surface and a part of the side surface of the recess.

11. The silicon carbide semiconductor device according to claim 1, wherein the metal electrode contains one of Ti, Ni, W, Mo, Au, and Pt.
